(19) United States
(12) Patent Application Publication
(10) Pub. No.: US 2003/0024479 A1
(43) Pub. Date: Feb. 6, 2003

(54) Vacuum deposition apparatus

(75) Inventors: Makoto Kashiwaya, Kanagawa (JP); Junji Nakada, Kanagawa (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/208,035

(22) Filed: Jul. 31, 2002

(30) Foreign Application Priority Data
Jul. 31, 2001 (JP) 2001-231370
Sep. 27, 2001 (JP) 2001-296364

(51) Int. Cl. C23C 16/00

(52) U.S. Cl. 118/726

(57) ABSTRACT

The vacuum deposition apparatus includes a vacuum chamber, a plurality of evaporation positions set in the vacuum chamber and provided with film-forming materials in such a way that a film-forming material is placed at a evaporation position, a heating device for heating each of the film-forming materials, and arranged in correspondence with each of the plurality of evaporation positions, and a feeding device for feeding one of the film-forming materials into one of the plurality of evaporation positions during film deposition, and arranged in correspondence with at least one of the plurality of evaporation positions. Accordingly, the vacuum deposition apparatus is able to form a thick deposited film by multiple-source vacuum deposition independently heating two or more film-forming materials.

### BACKGROUND OF THE INVENTION

1. Field of the Invention

The present invention relates to the field of technology for vacuum deposition apparatuses, and more particularly, to a vacuum deposition apparatus capable of forming a thick vacuum-deposited film from a plurality of film-forming materials.

2. Description of the Related Art

A phosphor is known which accumulates part of radiation energy when exposed to radiation rays (X-rays, α-rays, β-rays, γ-rays, electron rays, ultraviolet rays, or the like) and thereafter produces stimulated emission according to the accumulated energy when exposed to stimulating rays such as visible light or the like. This kind of phosphor is called a storage phosphor (stimulable phosphor) and finds various applications including medical applications.

For example, a radiographic image information recording/reproduction system using a sheet having a layer of such stimulable phosphor (hereinafter referred to as a phosphor layer) (the sheet hereinafter referred to as a phosphor sheet (also as a radiographic image conversion sheet)) is known. This system has been put into practical use, for example, as Fuji Computed Radiography (FCR).

In this system, a radiographic image information of an object, e.g., a human body is recorded on a phosphor sheet (phosphor layer); after recording, the phosphor sheet is two-dimensionally scanned with excitation light such as laser light to cause stimulated emission (luminescence); an image signal is obtained by photoelectrically reading light produced by the stimulated emission (luminescence); and an image reproduced on the basis of the image signal is output as a visible radiographic image of the object by being formed on a recording material such as a photographic sensitive material or on a display such as a cathode ray tube (CRT).

Ordinarily, a phosphor sheet used for this purpose is made by a process in which a coating material is prepared by dispersing powder of stimulable phosphor in a solution containing a binder, etc., and this coating material is applied to a surface of a sheet-like substrate made of glass or a resin and is dried.

Another phosphor sheet is also known which has a phosphor layer formed on a substrate by physical deposition (vapor phase film deposition) such as vacuum deposition or sputtering (see JP 2789194 B and JP 5-249299 A). A phosphor layer formed by deposition have fewer contents of impurities because it is formed in a vacuum, contains substantially no binder and no components other than the stimulable phosphor, and therefore have improved characteristics, i.e., smaller variation in performance and extremely high luminescence efficiency.

In most instances, a stimulable phosphor is formed of a base material and a microdoze of an additive called an activator.

Ordinarily, deposition for forming such a phosphor layer of stimulable phosphor is performed as one-source deposition such that a mixture containing a base material and an activator is prepared, or a compound or an alloy containing a base material and an activator is made, and the mixture, the compound, or the alloy is used and deposited as a film-forming material. In one-source deposition, however, the composition of the phosphor layer is determined by the prepared film-forming material and it is not possible to adjust the constituents or the like of the phosphor layer during film deposition.

In this respect, two-source deposition performed by using film-forming materials separately prepared as a base material and an activator and by independently controlling heating of each material is more advantageous.

Deposition is being used as a film forming method in various manufacturing fields, e.g., the field of coating on optical components, of manufacturing magnetic recording mediums, and of manufacturing electronic displays. The thickness of films formed by deposition in such fields is, in most cases, 1 μm or less, and at most 3 μm.

In contrast, a thick phosphor layer having a thickness of about 500 μm is required as the phosphor layer formed by deposition on the above-described phosphor sheet. In some cases, a phosphor layer having a thickness close to 1000 μm is required.

In a case where a phosphor layer is formed on a phosphor sheet by deposition, it is preferable to form by two-source deposition a phosphor film much thicker than ordinary thin films. However, no film deposition apparatus capable of deposition for such a purpose has been realized.

### SUMMARY OF THE INVENTION

The present invention has been made in view of the above and an object of the present invention is therefore to provide a vacuum deposition apparatus suitably used for manufacturing, for example, a deposited-type phosphor sheet on which a phosphor layer is formed by deposition, the apparatus being capable of forming a thick deposited film by multiple-source vacuum deposition independently heating two or more film-forming materials.

In order to attain the object described above, the present invention provides a vacuum deposition apparatus comprising a vacuum chamber, a plurality of evaporation positions set in the vacuum chamber and provided with film-forming materials in such a way that a film-forming material is placed at a evaporation position, heating means for heating each of the film-forming materials, and arranged in correspondence with each of the plurality of evaporation positions, and feeding means for feeding one of the film-forming materials into one of the plurality of evaporation positions during film deposition, and arranged in correspondence with at least one of the plurality of evaporation positions.

It is preferable that the heating means comprises at least one of an electron gun which emits an electron beam onto the film-forming material placed at the evaporation position to heat and evaporate the film-forming material, or resistance heating means which applies resistance heating to the film-forming material placed at the evaporation position to evaporate the film-forming material.

Preferably, the electron gun is a deflecting type electron gun.

It is preferable that the feeding means feeds the film-forming material into the evaporation position according to consumption of the film-forming material being evaporated at the evaporation position.

It is preferable that a container for containing one film-forming material is placed at the evaporation position corresponding to at least one of the two or more film-forming materials which are different from each other.

It is preferable that the feeding means comprises a cylinder projecting down from the evaporation position through and out of the vacuum chamber and being filled with the film-forming material, a piston loosely fitted in the cylinder and moving along a vertical direction, and a motor for driving the piston.

It is preferable that the feeding means comprises a rail having a groove extending in a direction to be filled with the film-forming material and extending sideward from the evaporation position through and out of the vacuum chamber, a piston fitted to slide and reciprocate in the groove, and a motor for driving the piston.

It is preferable that the feeding means comprises a film deposition turret on which a plurality of containers containing one of the film-forming materials are laid on its identical circumference and which is rotated such that the containers laid on the film deposition turret are supplied into the evaporation position one after another, and rotary drive means for driving the film deposition turret to be rotated.

Preferably, the feeding means further comprises discharge means for discharging an emptied container from the film deposition turret when one of the film-forming materials contained therein is used up.

Preferably, the feeding means further comprises a feed turret arranged close to the film deposition turret to lay a plurality of containers containing the one of the film-forming materials along its identical circumference thereon, rotary drive means for driving the film deposition turret to be rotated, pressing means for pressing the containers laid on the feed turret in a radial direction when being close to the film deposition turret and moving the containers from the feed turret to the film deposition turret, and discharge means for discharging an emptied container from the film deposition turret when the one of the film-forming material contained therein is used up.

It is preferable that the feeding means comprises a rotary crucible having a circular groove for containing the film-forming material and passing through the evaporation position and rotary drive means for driving the rotary crucible to be rotated.

Preferably, the feeding means further comprises a film-forming material tank for feeding the film-forming material into an empty portion of the groove, which is apart from the evaporation position.

Preferably, the feeding means comprises a plurality of rotary crucibles to be rotated about a same center and rotary drive means for driving each of the plurality of rotary crucibles to be rotated.

Preferably, the heating means comprises a 90° deflecting electron gun including a straight-beam type electron gun and a 90° deflecting coil, the 90° deflecting electron gun emitting an electron beam onto the film-forming material placed at the evaporation position, and thereby heating and evaporating the film-forming material.

It is preferable that the plurality of evaporation positions are provided with a crucible having a plurality of sets of containing portions which contain a plurality of corresponding film-forming materials respectively, and that the feeding means comprises a sub chamber for containing a new replacement crucible having the same constitution as the crucible and fixed to the outside of the vacuum chamber and a gate valve for communicating the sub chamber with the vacuum chamber and a crucible interchange mechanism for interchanging the used crucible in the vacuum chamber with a new replacement crucible and provided in the sub chamber.

It is preferable that the film-forming material includes two or more types of film-forming materials which are different from each other.

It is preferable that the film-forming material includes cesium halide and europium halide to form a phosphor layer made of a stimulable phosphor sheet.

It is preferable that the film-forming material includes cesium halide and europium halide to form a phosphor layer made of a stimulable phosphor sheets, and that the heating means includes an electron gun for emitting an electron beam onto the cesium halide placed at the evaporation position and thereby heating and evaporating the cesium halide, and resistance heating means for applying resistance heating on the europium halide placed at the evaporation position and thereby heating and evaporating the europium halide.

### BRIEF DESCRIPTION OF THE DRAWINGS

In the accompanying drawings:

FIG. 1 is a diagram schematically showing an example of a vacuum deposition apparatus of the present invention;

FIGS. 2A and 2B are a schematic top view and a schematic front view, respectively, of a heating evaporator in the vacuum deposition apparatus shown in FIG. 1;

FIGS. 3A and 3B are a schematic top view and a schematic front view, respectively, of another example of the heating evaporator used in the vacuum deposition apparatus of the present invention;

FIG. 4 is a schematic top view of still another example of the heating evaporator used in the vacuum deposition apparatus of the present invention;

FIGS. 5A and 5B are a schematic top view and a schematic front view, respectively, of a further example of the heating evaporator used in the vacuum deposition apparatus of the present invention;

FIGS. 6A and 6B are a schematic top view and a schematic front view, respectively, of still a further example of the heating evaporator used in the vacuum deposition apparatus of the present invention;

FIGS. 7A and 7B are a schematic top view and a schematic front view, respectively, of still a further example of the heating evaporator used in the vacuum deposition apparatus of the present invention;

FIG. 8 is a schematic diagram of another example of the vacuum deposition apparatus of the present invention; and

FIG. 9 is a schematic diagram of still another example of the vacuum deposition apparatus of the present invention.

### DESCRIPTION OF THE PREFERRED EMBODIMENTS

A vacuum deposition apparatus which represents a preferred embodiment of the present invention will be described in detail with reference to the accompanying drawings.

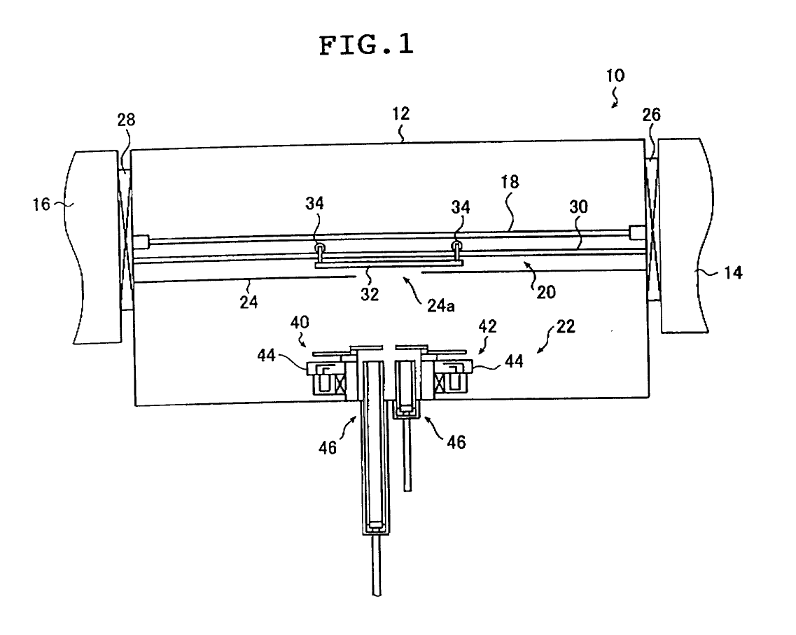

FIG. 1 schematically shows an embodiment of a vacuum deposition apparatus in accordance with the present invention.

A vacuum deposition apparatus 10 shown in FIG. 1 is an apparatus for performing two-source vacuum deposition, i.e., a load-lock type vacuum deposition apparatus basically constituted by a vacuum chamber 12, a loading chamber 14, an unloading chamber 16, a sheath heater 18, a substrate conveying mechanism 20, a heating evaporator 22, and a partition 24. A vacuum pump (evacuation means) (not shown) for evacuating the interior of the vacuum chamber 12 to a predetermined degree of vacuum is connected to the vacuum chamber 12.

The vacuum deposition apparatus 10 illustrated in FIG. 1 performs, for example, two-source vacuum deposition using cesium bromide (CsBr) and europium bromide (EuBrₓ (ordinarily x is 2 or 3)) as film-forming materials to form a phosphor layer of stimulable phosphor CsBr:Eu on a substrate, thereby making the above-described phosphor sheet.

The vacuum chamber 12 is a well-known vacuum chamber (belljar, vacuum vessel) formed, for example, of iron, stainless steel, or aluminum and used in vacuum deposition apparatuses. In the illustrated embodiment of the apparatus, the interior of the vacuum chamber 12 is separated by the partition 24 having an opening 24a into an upper section, i.e., the side of substrate conveying mechanism 20 and a lower section, i.e., the side of heating evaporator 22.

As mentioned above, the vacuum pump is connected to the vacuum chamber 12. There is no particular restriction on the selection of the vacuum pump. Any of various vacuum pumps used in vacuum deposition apparatuses may be used if it is capable of evacuating to the necessary degree of vacuum. For example, an oil diffusion pump, a cryopump, or a turbomolecular pump may be used. A cryocoil or the like may also be used as an auxiliary means. In the vacuum chamber 12 of the illustrated vacuum deposition apparatus 10 for film deposition of the above-described phosphor layer, the degree of vacuum to be reached is preferably 5×10⁻⁵ Torr or less and, more preferably, 3×10⁻⁶ Torr or less.

The loading chamber 14 and the unloading chamber 16 are the same as those in ordinary load-lock type vacuum deposition apparatuses. That is, the loading chamber 14 is a chamber through which a substrate on which film is to be formed is loaded, and the unloading chamber 16 is a chamber through which a substrate on which a film has been formed is taken out. Only one substrate or a plurality of substrates may be accommodated in each of the loading chamber 14 and the unloading chamber 16.

Gate valves 26 and 28 each of which is operated to maintain the degree of vacuum in the vacuum chamber 12 when the loading chamber 14 or the unloading chamber 16 is opened to atmosphere in order to load or unload a substrate are respectively provided between connected portions of the loading chamber 14 and the vacuum chamber 12 and between connected portions of unloading chamber 16 and the vacuum chamber 12.

The substrate conveying mechanism 20 is arranged to convey a substrate from the loading chamber 14 to a film-forming position (at the opening 24a of the partition 24) and into the unloading chamber 16.

The sheath heater 18 for heating a substrate from the back surface (non-film-deposition surface) side is placed above the substrate conveying mechanism 20.

In the illustrated embodiment of the vacuum deposition apparatus, the substrate conveying mechanism 20 is constituted by a guide rail 30, a substrate holder 32, and a conveyer means (not shown), for example.

The guide rail 30 extends from the loading chamber 14 to the unloading chamber 16 and is fixed at a predetermined position in the vacuum chamber 12 by a well-known means using a stay or the like.

In the illustrated embodiment of the vacuum deposition apparatus, the substrate holder 32 is a frame which supports a substrate (film deposition substrate) on which a phosphor layer is formed, and which also functions as a mask on the film deposition surface of the substrate. The substrate holder 32 has wheels 34 placed on and engaged with the guide rail 30. The substrate holder 32 held and guided by the guide rail 30 while being suspended from the same is moved from the loading chamber 14 into the unloading chamber 16 by the conveyer means (not shown). There is no particular restriction on the selection of the means for moving the substrate holder 32. A screw transmission, a rack and pinion gear set, or any other well-known means may be used as the moving means.

The heating evaporator 22 is placed below the substrate conveying mechanism 20 etc., from which it is isolated by the partition 24.

As mentioned above, the vacuum deposition apparatus 10 performs two-source vacuum deposition by using cesium bromide and europium bromide as film-forming materials (evaporation sources) and by separately heating these materials. The heating evaporator 22 has a cesium evaporation section 40 (hereinafter referred to as “Cs evaporation section 40”) and an europium evaporation section 42 (hereinafter referred to as “Eu evaporation section 42”).

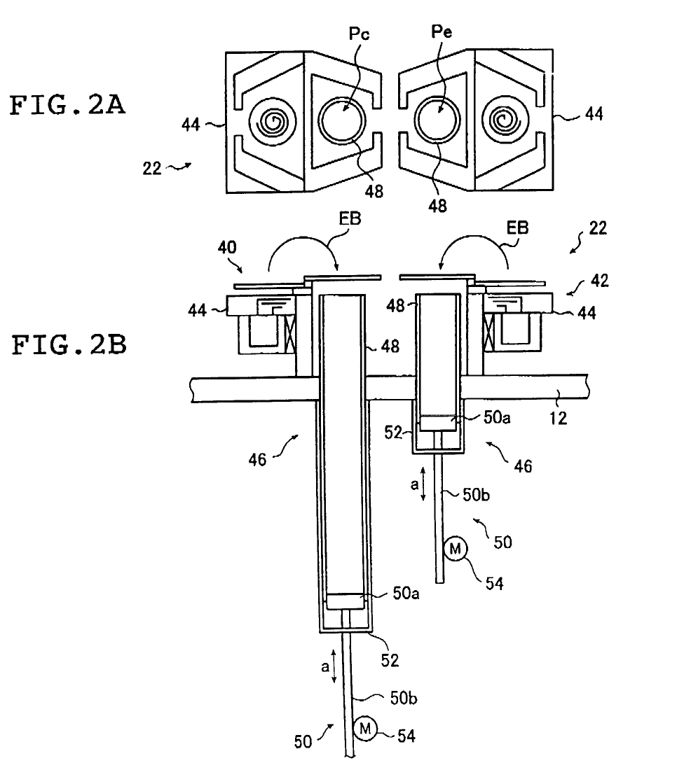

FIGS. 2A and 2B schematically show the heating evaporator 22.

FIGS. 2A and 2B are a top view (seen from above in FIG. 1) and a front view (seen in the same direction as in FIG. 1), respectively, of the heating evaporator 22. The Cs evaporation section 40 and the Eu evaporation section 42 are basically identical in construction to each other, and identical members of these units are indicated by the same reference symbols. A common description will be given of the same portions. Only differences will be described separately.

Each of the Cs evaporation section 40 and the Eu evaporation section 42 has a deflecting type electron gun 44 (hereinafter referred to as “deflecting gun 44”) and a material feeding means 46.

The deflecting gun 44 is a heating source similar to those used in various vacuum deposition apparatuses. The deflecting gun 44 produces an electron beam (EB) and applies this beam to the film-forming material at a predetermined evaporation position to evaporate the film-forming material. In the illustrated embodiment of the vacuum deposition apparatus, a 180° deflecting gun which deflects the EB through 180° before the EB reaches the evaporation position is used as the deflecting gun 44. In the present invention, the electron gun is not limited to the 180° deflecting gun, and any of other various electron guns, e.g., a 270° deflecting gun, a straight-beam gun, a 90° deflecting gun, which is used in another embodiment of the present invention described below, may be used.

In the present invention, the emission current and the EB acceleration voltage of the deflecting gun 44 are not limited to particular values. The emission current and the EB acceleration voltage may be set to sufficient values according to the film-forming material and the thickness of the film to be formed. To adjust the ratio of the components in the film, the outputs of the deflecting guns 44 may be controlled as in ordinary two-source vacuum deposition.

In the illustrated embodiment of the vacuum deposition apparatus, it is preferred that the EB acceleration voltage be −1 kV to −30 kV, the emission current in the Cs evaporation section 40 be 50 mA to 2A, and the emission current in the Eu evaporation section 42 be 10 mA to 500 mA (the rate of evaporation of Eu is extremely small in comparison with the rate of evaporation of Cs, as described below).

In the present invention, the means for heating the film-forming material is not limited to the electron gun (EB) and any of other various means, e.g., resistance heating may alternatively be used. However, the electron gun is preferred from the viewpoint of controllability and the like.

In the illustrated embodiment of the vacuum deposition apparatus, different heating means may be used for two-source (multiple-source) vacuum deposition. For example, while heating of cesium bromide is performed by using the electron gun, heating of europium bromide is performed by resistance heating.

The material feeding means 46 feeds the film-forming material, i.e., cesium bromide in the Cs evaporation section 40, or europium bromide in the Eu evaporation section 42, to the predetermined evaporation position (the position at which the material is irradiated with the EB from the deflecting gun 44).

In the illustrated embodiment of the vacuum deposition apparatus, the two sets of material feeding means 46 in the two evaporation sections are basically similar in construction to each other. Each set of material feeding means 46 is constituted by a cylinder 48, a piston 50, a casing 52, and a lift means (motor) 54.

The cylinder 48 is fixed on a wall surface of the vacuum chamber 12 in a state of passing through the bottom surface of the vacuum chamber 12 and having its portion projecting outside the vacuum chamber 12, its upper end portion corresponding to the EB irradiation position. That is, in the illustrated embodiment, the cylinder 48 is a hearth with an upper end portion corresponding to the material evaporation position P (cesium bromide evaporation position Pc, europium bromide evaporation position Pe).

The piston 50 is constituted by a cylindrical piston head 50a loosely fitted in the cylinder 48, and a piston rod 50b. The piston head 50a is fixed to an end of the piston rod 50b. The lift means 54 for moving the piston 50 along a vertical direction (indicated by arrows a) is engaged with the piston rod 50b.

The open end of the cylinder 48 is closed with the casing 52 to maintain the interior of the vacuum chamber 12 in a gastight state, while the piston rod 50b is axially supported by a bearing (not shown) on the casing 52 in a gastight manner so as to be reciprocatingly movable along the above-mentioned vertical direction.

The film-forming material is formed into a cylindrical shape having a diameter slightly smaller than the inside diameter of the cylinder 50, and is accommodated in the cylinder 48 in a state of being placed on the piston head 50a. As the film-forming material placed at the evaporation position is consumed for film deposition on the substrate, the lift means 54 is correspondingly driven to lift the cylindrical film-forming material. The film-forming material is thereby fed constantly to the upper surface of the cylinder 48, i.e., the evaporation position.

Thus, the vacuum deposition apparatus 10 having the heating evaporator 22 is capable of forming a thick film having a thickness exceeding 200 μm by two-source vacuum deposition using a plurality of film-forming materials. Therefore the vacuum deposition apparatus 10 can be suitably adapted to vacuum-deposition film forming of the phosphor layer of the above-described phosphor sheet.

In the phosphor layer formed by using CsBr:Eu as a stimulable phosphor in the illustrated embodiment, the Eu/Cs ratio in the stimulable phosphor is, in terms of mol concentration ratio, about 0.003/l, that is, the amount of europium is extremely small in comparison with that of cesium and is on an impurity level.

In the illustrated embodiment of the vacuum deposition apparatus, therefore, the amount of cesium bromide loaded in the Cs evaporation section 40 is set larger than that of europium bromide loaded in the Eu evaporation section 42. In a case where the present invention is applied to two-source (multiple-source) vacuum deposition with such a large difference between the evaporation rates, the arrangement may otherwise be made such that the film-forming material evaporated at the lower rate is not fed by the material feeding means but contained in a hearth (hearth liner) or the like to be placed at the predetermined evaporation position, as in the case of ordinary vacuum deposition. That is, according to the present invention, the material feeding means may be provided in correspondence with at least one film-forming material.

According to the present invention, the film-forming material in the shape of a column (a tablet described below) may be formed by a well-known method. For example, a method may be used in which powder of a film-forming material is formed by being put in forming dies in a powder compactor and thereafter undergoes vacuum drying.

While, the film-forming material formed into a cylindrical shape is used in the illustrated embodiment of the vacuum deposition apparatus, the shape of the film-forming material in this embodiment is not limited to the illustrated cylindrical shape. The film-forming material may be fed in the shape of a prism by the same mechanism.

In a system for multiple-source vacuum deposition, particularly the illustrated embodiment of the vacuum deposition apparatus, in which a large difference is set between the evaporation rates, it is preferable to set the evaporation positions of the film-forming materials close to each other in order to obtain a high-quality film by uniformly distributing the different components.

In the illustrated embodiment, the two evaporation sections (Cs evaporation section 40 and the Eu evaporation section 42) are disposed by being oriented in opposite directions so that the evaporation positions (material feed positions) are set adjacent to each other, thus setting the evaporation positions of the two-source film forming materials close to each other.

In the vacuum deposition apparatus of the present invention, the distance between the evaporation positions of the film-forming materials is not particularly specified. However, in a case where the components to be deposited from multiple-source film-forming materials, which include a component on an impurity level in particular, should be deposited by being uniformly distributed to form a thin film having a thickness of 20 μm or more, and further 200 μm, it is preferable to place the film-forming materials so that the evaporation positions of the film-forming materials are set close to each other as described above, and so that the center of the substrate and the center of the film-forming material (evaporation source) coincide with each other. The impurity level referred to in the specification of the present invention is 1% or less in terms of mol concentration.

Also, the positional relationship between the evaporation positions of the film-forming materials is not particularly specified. It may be optimized in such a range that mixture vapor flow can be obtained. Also, it is preferable to place a regulating plate or the like in order to improve the uniformity of the mixture vapor flow.

Also, the diameter of the cylinder 48 (in a case an ordinary hearth (hearth liner) is used, the size of the hearth, or, in a case where a rotary crucible is used, the width of the rotary crucible) is not particularly specified. However, it is preferable to optimize the diameter or the size in such a range that the EB produced by the electron gun can be applied to the evaporation position.

In the present invention, the distance between the evaporation position of each film-forming material and the substrate (film-forming position) is not particularly specified. However, it is preferable to optimize this distance in such a range that the film thickness distribution and the deposition efficiency are practically satisfactory.

In the vacuum deposition apparatus 10 called a load-lock type as mentioned above, film deposition is performed as described below. First, a substrate is held on the substrate holder 32 and is loaded in the loading chamber 14 at a predetermined position. The substrate is set so the film deposition surface faces downward in the vacuum chamber 12.

When the predetermined degree of vacuum in the vacuum chamber 12 (also in the loading chamber 14 and the unloading chamber 16) is reached after an instruction has been given to start film deposition, the gate valve 26 is opened and the substrate conveying mechanism 20 starts conveying the substrate holder 32 toward the unloading chamber 16. Also, the sheath heater 18 heats from the back side of the substrate conveyed by the substrate conveying mechanism 20.

If another substrate is newly loaded in the loading chamber 14, the gate valve 26 is closed at a point when the substrate holder 32 is moved out of the loading chamber 14.

When the substrate (the film deposition region of the substrate) is conveyed to a point immediately before the position corresponding to the opening 24a of the partition 24, the operation of the deflecting guns 44 is started to apply the EBs to the evaporation positions P. The film-forming materials (cesium bromide and europium bromide) are thereby evaporated to start deposition of CsBr:Eu, i.e., film forming of the phosphor layer, on the substrate.

When, by further conveyance of the substrate holder 32, the film deposition region of the substrate is moved apart from the position above the opening 24a of the partition 24, the operation of the deflecting guns 44 is stopped to terminate film deposition. The substrate holder 32 conveyance speed (i.e., the film deposition time), the outputs of the deflecting guns 44, etc., may be set as desired according to the film deposition rate and the thickness of the film to be formed. In this embodiment, it is preferable to set the film deposition rate to 10 to 5000 nm/sec.

The substrate holder 32 holding the substrate after the completion of film deposition is further conveyed to be accommodated in the unloading chamber 16. To enable the substrate to be taken out after the completion of film deposition, the gate valve 28 is closed at a point when the substrate holder 32 is accommodated in the unloading chamber 16.

In the illustrated embodiment of the vacuum deposition apparatus 10, film deposition is basically completed by one movement (one path) for conveying a substrate from the loading chamber 14 to the unloading chamber 16. However, the present invention is not limited to this. Film deposition may be performed by reciprocatingly conveying a substrate by the substrate conveying mechanism 20 one time or a certain number of times.

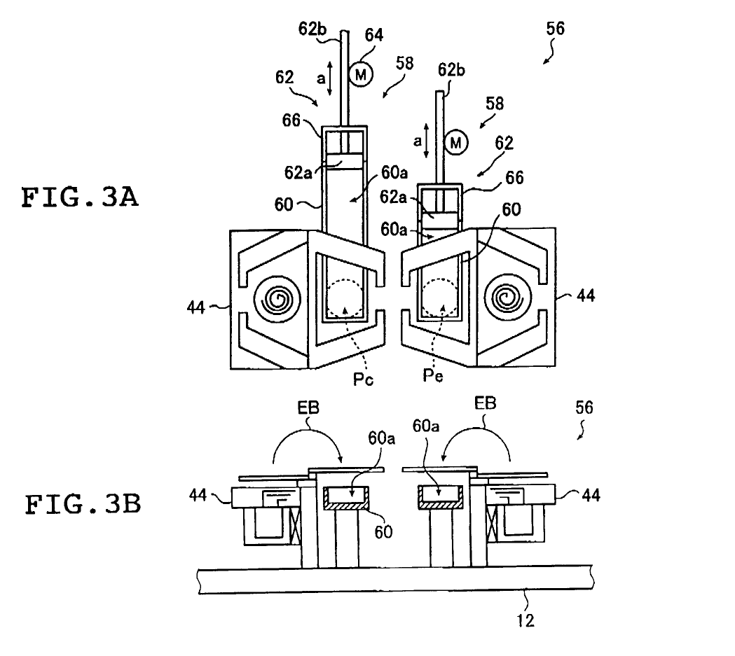

FIGS. 3A and 3B schematically show another embodiment of the heating evaporator used in the vacuum deposition apparatus 10 of the present invention.

FIGS. 3A and 3B are also a top view (seen from above in FIG. 1), respectively, as are FIGS. 2A and 2B. The embodiment of the heating evaporator shown in FIGS. 3A and 3B has the same construction as that of the embodiment shown in FIGS. 2A and 2B except for the construction of the material feeding means. Components in this embodiment identical to those described above are indicated by the same reference symbols. A description will be given mainly of different portions.

A heating evaporator 56 shown in FIGS. 3A and 3B is arranged to evaporate two-source film-forming materials by using deflecting guns 44 each of which is a 180° deflecting gun similar to that in the above-described embodiment of the heating evaporator.

While in the above-described embodiment the material feeding means 46 feeds the film forming material from a place below outside the vacuum chamber 12, material feeding means 58 in the embodiment shown in FIGS. 3A and 3B feeds the film-Forming material to the evaporation position from a place laterally located by the side within the vacuum chamber 12.

A Cs evaporation section and an Eu evaporation section are shown in a left-hand section and a right-hand section, respectively, of each of FIGS. 3A and 3B. The Cs evaporation section and the Eu evaporation section respectively have material feeding means 58 constructed in the same manner.

Each material feeding means 58 is constituted by a rail member 60 having a generally U-shaped cross-sectional configuration such that a channel (groove) 60a extends therein in one direction, a piston 62 having a pressing portion 62a loosely fitted in the channel (groove) 60a of the rail member 60 and a piston rod 62b having an end on which the pressing portion 62a is fixed, and a moving means (motor) 64 engaged with the piston rod 62b and operated to reciprocatingly move the piston 62 along the direction in which the channel 60a extends (the direction of arrow a). The piston rod 62b is axially supported by a supporting member 66 having a bearing (not shown) so as to be reciprocatingly movable along the direction of extension of the channel 60a. The rail 60 may be provided with a cover which covers the film-forming material except the portion at the evaporation position P.

In this heating evaporator 56, the film-forming material used is formed into the shape of a quadratic prism such as to be loosely fitted in the channel 60a.

This film-forming material is loaded by being contained in the channel 60a with its one side opposite from the side at the evaporation position in contact with the pressing portion 62a.

This heating evaporator 56 evaporates the film-forming materials basically in the same manner as the above-described heating evaporator 22 except that the film-forming material feed direction is different.

For example, the evaporation position P (Pc or Pe) of each film-forming material is set on a portion of the rail member 60 indicated by a circle (dotted line) in the vicinity of an end portion of the rail member 60. The deflecting gun 44 applies the EB to the film-forming material at this position to perform vacuum deposition. As the film-forming material at the evaporation position is consumed by film deposition, the moving means 64 correspondingly moves the piston rod 62b toward the evaporation position to press the film-forming material by the pressing portion 62a, thereby feeding the film-forming material to the evaporation position.

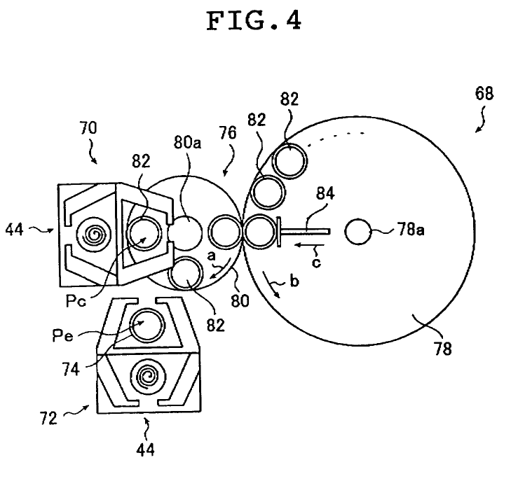

FIG. 4 is a top view of still another embodiment of the heating evaporator used in the present invention.

While a film-forming material formed into a columnar shape is used in the above-described embodiments of the heating evaporator, a film-forming material formed into the shape of a tablet or a granular film-forming material is loaded at the evaporation position by being contained in a container such as a hearth liner and is evaporated by the same deflecting gun 44 in the example shown in FIG. 4.

The heating evaporator indicated by reference numeral 68 in FIG. 4 has a Cs evaporation section indicated by reference numeral 70, and a Eu evaporation section indicated by reference numeral 72.

In the embodiment shown in FIG. 4, the Eu evaporation section 72 has no material feeding means, and europium bromide provided as a film-forming material is contained in a hearth (hearth liner) 74, as is that in ordinary vacuum deposition apparatuses. However, the present invention is not limited to this arrangement. The Eu evaporation section 72 may have means for feeding europium bromide.

In the Cs deposition unit 70, a material feeding means 76 has two turrets: a feed turret 78 and a film deposition turret 80, on which containers 82 containing cesium bromide as a film-forming material are laid or mounted. The two turrets, each having a circular shape as viewed from above, are placed so that their circumferential portions are brought extremely close to each other. The two turrets are respectively rotated intermittently in directions indicated by arrows a and b about centers (78a and 80a) by a rotating means (not shown). On the feed turret 78, a pressing means 84 for pressing one of the containers 82 in a radial direction (arrow c) from the center 78a toward the film deposition turret 80 is placed. Pressing of the container 82 by the pressing means 84 may be performed on the basis of a well-known method.

When cesium bromide contained in the container 82 placed at the evaporation position is used up by evaporation using irradiation with the EB from the deflecting gun 44, operation of the deflecting gun 44 is stopped and each of the film deposition turret 80 and the feed turret 78 is turned through a predetermined angle and stopped.

When the rotation of the turrets is stopped, the operation of the deflecting gun 44 is again started to restart film deposition. The emptied container 82 is immediately discharged or removed from the film deposition turret 80 by a well-known discharge or remove means such as a robot arm (not shown). Also, when the rotation of the turrets is stopped, the pressing means 84 is operated in on the feed turret 78 to place one container 82 on the film deposition turret 80.

In this manner, even when cesium bromide contained in the container 82 at the evaporation position Pc is used up, another container 82 containing a sufficient amount of cesium bromide therein can be immediately supplied.

In the illustrated embodiment, the evaporation position Pc and the centers of rotation of the two turrets are set on a straight line, the angle of the film deposition turret 80 is set to 90°, and the rotation angle of the feed turret 78 and the mounting position of the container 82 are set so that, when the turrets are stopped, the center of one of the containers placed so as to face the film deposition turret 80 is unfailingly positioned on the above-mentioned straight line, thus realizing correct feeding of each container 82 to the evaporation position Pc. The sequence of operations, the positions in which the turrets are placed, etc., are not limited to those described above.

Tablets of the film-forming material may be supplied to the evaporation position Pc in a similar manner without using the containers 82.

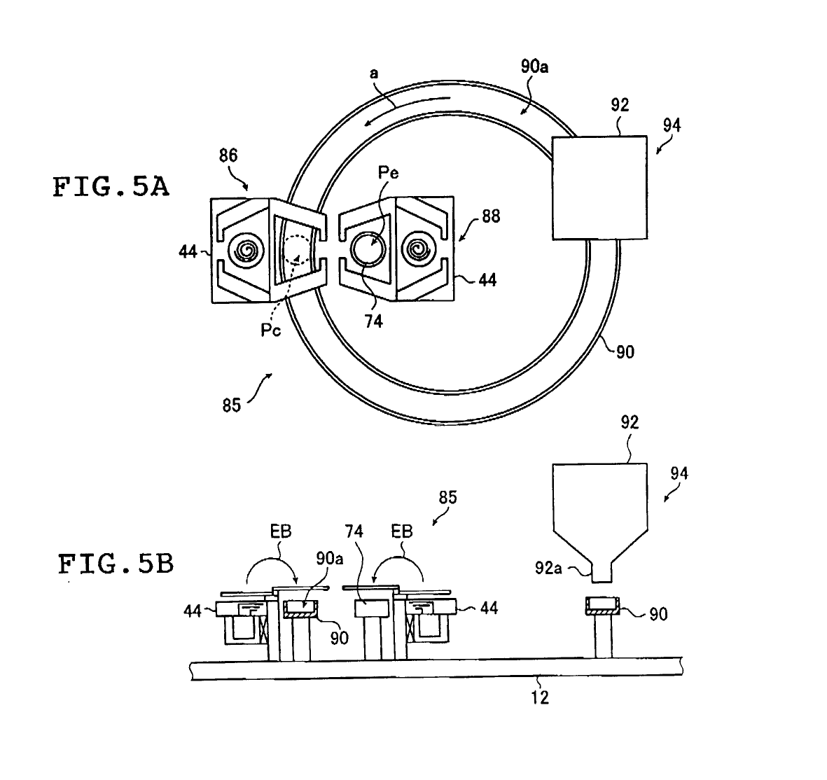

FIGS. 5A and 5B schematically show a further embodiment of the heating evaporator. FIGS. 5A and 5B are also a top view and a front view, respectively.

A heating evaporator 85 shown in FIGS. 5A and 5B also uses as a heating source a deflecting gun 44 which is the same 180° deflecting gun as those described above. The heating evaporator 85 has a Cs evaporation section, indicated by reference numeral 86, and a Eu evaporation section, indicated by reference numeral 88. Also in this example, the Eu evaporation section 88 has no material feeding means, and europium bromide provided as a film-forming material is contained in a hearth (hearth liner) 74. Also, the Eu evaporation section 88 may have means for feeding europium bromide.

The Cs evaporation section 86 has, in addition to the deflecting gun 44, a material feeding means 94 constituted by a rotary crucible 90 and a material (cesium bromide) tank 92.

The rotary crucible 90 in the shape of a circular ring has a channel 90a for containing the film-forming material formed in its upper surface along the entire circumference, and has a generally U-shaped cross section. The rotary crucible 90 is rotated about a center of the ring (circle) in the direction of arrow a shown in the drawing by a rotating means (not shown). The evaporation position Pc of the film-forming material (EB irradiation position) is set above a place in which a portion of the channel 90a exists.

The material tank 92 is a tank containing granular cesium bromide. The material tank 92 has an open/closable discharge port 92a formed at its bottom and is placed so that the discharge port 92a faces the channel 90a of the rotary crucible 90.

In the thus-constructed Cs evaporation section 86, when the amount of cesium bromide at the evaporation position Pc is reduced to a predetermined amount or less by film deposition, the rotary crucible 90 is rotated through a predetermined angle corresponding to the evaporation position Pc. During this rotation, the discharge port 92a of the material tank 92 is opened to feed cesium bromide into the channel 90a. Thus, when cesium bromide is consumed, feed of cesium bromide to the evaporation position Pc can be immediately performed.

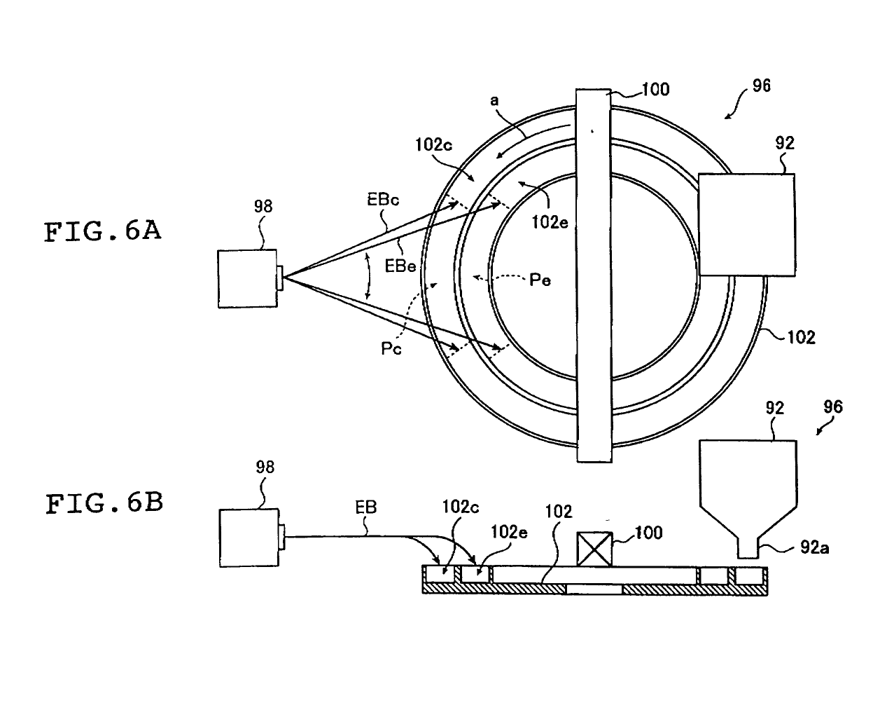

FIGS. 6A and 6B schematically show still a further embodiment of the heating evaporator. FIGS. 6A and 6B are also a top view and a front view, respectively.

A heating evaporator 96 shown in FIGS. 6A and 6B uses not the deflecting gun 44 but a straight-beam type electron gun 98 (hereinafter referred to as “straight-beam gun 98”). The heating evaporator 96 uses the straight-beam gun 98 and a 90° deflecting coil 100 (hereinafter referred to as “deflecting coil 100”) to apply EBs to evaporation positions P (Pc and Pe). The heating evaporator 96 heats and evaporates film-forming materials by using the 90° deflecting straight-beam gun. In the illustrated embodiment, the heating evaporator 96 has, in addition to this heating means, a material feeding means constituted by a rotary crucible 102 and a material tank 92 for filling the rotary crucible 102 with cesium bromide.

The rotary crucible 102 in the shape of a disk has a two channels (grooves): a channel (groove) 102c for containing cesium bromide and a channel 102e for containing europium bromide, formed in its upper surface along the entire circumference. The rotary crucible 102 is rotated in the direction of arrow a shown in the drawing by a rotating means (not shown), as is that in the preceding embodiment of the heating evaporator. As indicated by the dotted lines in FIG. 6A, the area defined in an elongated form as the cesium bromide evaporation position Pc (EBc irradiation position) is set above a place in which a portion of the channel 102c exists and the area also defined in a similar form as the europium bromide evaporation position Pe (EBe irradiation position) is set above a place in which a portion of the channel 102e exists.

The material tank 92 similar to that in the preceding embodiment of the heating evaporator is placed in correspondence with the channel 102c for containing cesium bromide.

In the heating evaporator 96 in the illustrated embodiment, the film-forming materials are scanned along the respective evaporation positions P with EBs emitted from the straight-beam gun 98 (90° deflecting straight-beam gun) to be evaporated, thereby performing film deposition.

When the amount of the film-forming material contained in the channel (groove) at the evaporation position P (mainly the film-forming material at the evaporation position Pc) is reduced to a predetermined amount or less by film deposition, the rotary crucible 102 is rotated through a predetermined angle corresponding to the evaporation position P. During this rotation, the discharge port 92a of the material tank 92 is opened to feed cesium bromide into the channel 102c, as in the preceding embodiment of the heating evaporator. Thus, sufficient amounts of film-forming materials can always be fed to the two evaporation positions Pc and Pe.

In each of the arrangements shown in FIGS. 5 and 6, using the rotary crucible 90 or the like, film deposition may be stopped when the rotary crucible 90 is rotated, or the rotation of the rotary crucible 90 may be continued while film deposition is being performed.

The arrangement may alternatively be such that, instead of filling the channels or grooves of the rotary crucible with granular film-forming materials, feeding of the film-forming materials is performed by placing on a similar annular member containers such as hearth liners containing the film-forming materials or tablets of the film-forming materials.

In the illustrated embodiment of the heating evaporator the film-forming materials are evaporated by being irradiated with EBs from the straight-beam gun 98. However, the present invention is not limited to this arrangement. In an arrangement using the straight-beam gun 98 is used, such scanning may be used or any other method, e.g., a method in which EBs may be applied to one position or a plurality of evaporation positions set as desired to evaporate the film-forming materials may be used.

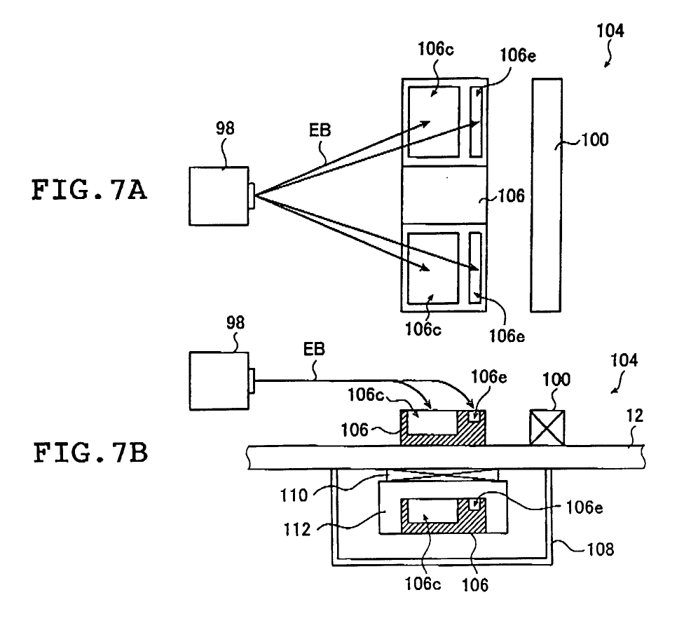

FIGS. 7A and 7B schematically show still a further embodiment of the heating evaporator. FIGS. 7A and 7B are also a top view and a front view, respectively.

A heating evaporator 104 shown in FIGS. 7A and 7B uses as a heating source the same 90° deflecting straight-beam gun constituted by a straight-beam gun 98 and a deflecting coil 100 as that in the embodiment shown in FIGS. 6A and 6B. A crucible 106 having a Cs containing portion 106c in which cesium bromide is contained and an Eu containing portion 106e in which europium bromide is contained is placed between the straight-beam gun 98 and the deflecting coil 100.

In this illustrated embodiment, two sets of containing portions each consisting of the Cs containing portion 106c on the side of straight-beam gun 98 and the Eu containing portion 106e on the side of deflecting coil 100 placed in this order along the directions of emission of EBs are provided in the crucible 106. The evaporation positions P of the film-forming materials are set respectively in correspondence with the containing portions of the crucible 106.

This heating evaporator 104 has a sub chamber 108 which is fixed to the bottom surface of the vacuum chamber 12, and which communicates with the interior of the vacuum chamber 12. A communication section between these chambers is open/closable in gastight manner by a gate valve 110.

In the sub chamber 108, a crucible interchange mechanism 112 (hereinafter referred to as “interchange mechanism 112”) is provided which holds the same crucible 106 as that described above, and which interchanges the crucible 106 in the vacuum chamber 12 and the crucible 106 that it holds. A vacuum pump (not shown) is connected to the sub chamber 108.

In the heating evaporator 104 in the illustrated embodiment, the electron beams (Ebs) emitted from the straight-beam gun 98 are applied to the film-forming materials at one of the two sets of the containing portions of the crucible 106 (e.g., the upper one as viewed in FIG. 7A=the remoter one as viewed in FIG. 7B) to perform film deposition. When one of or both of the film-forming materials (even either one of cesium bromide and europium bromide) in the containing portions is/are used up, the EBs are applied to the other set of the containing portions of the crucible 106 to perform film deposition. In this state, the gate valve 110 is closed.

While film deposition is being performed in this manner, the crucible 106 in which the containing portions are filled with the film-forming materials is loaded in the interchange mechanism 112 in the sub chamber 108 and the interior of the sub chamber 108 is evacuated to the predetermined degree of vacuum.

When the film-forming materials in the crucible 106 in the vacuum chamber 12 are used up, application of EBs from the straight-beam gun 98 is stopped and the gate valve 110 is opened. The interchange mechanism 112 then interchanges the crucible 106 in the vacuum chamber 12 and the crucible 106 that it holds, and the gate valve 110 is closed. Interchange of crucibles 106 by the interchange mechanism 112 may be performed by using well-known means.

When the predetermined pressure in the vacuum chamber 12 is thereafter reached, the straight-beam gun 98 is driven to restart vacuum deposition. On the other hand, the sub chamber 108 is opened, the emptied crucible 106 is discharged or removed, another crucible 106 filled with the film-forming materials is loaded, and the sub chamber 108 is closed, followed by evacuation in the sub chamber 108.

The heating evaporators shown in FIGS. 2A to 7B can be used in various vacuum deposition apparatuses, including the load-lock type shown in FIG. 1.

The electron gun used in each heating evaporator is not limited to the described embodiment. For example, in the arrangement using the 180° deflecting gun described above by way of example, a 90° deflecting gun, if possible, may be used according to the constructions and scales of the vacuum deposition apparatus and the heating evaporator. Also, different material feeding means may be used with respect to the film-forming materials (evaporation positions).

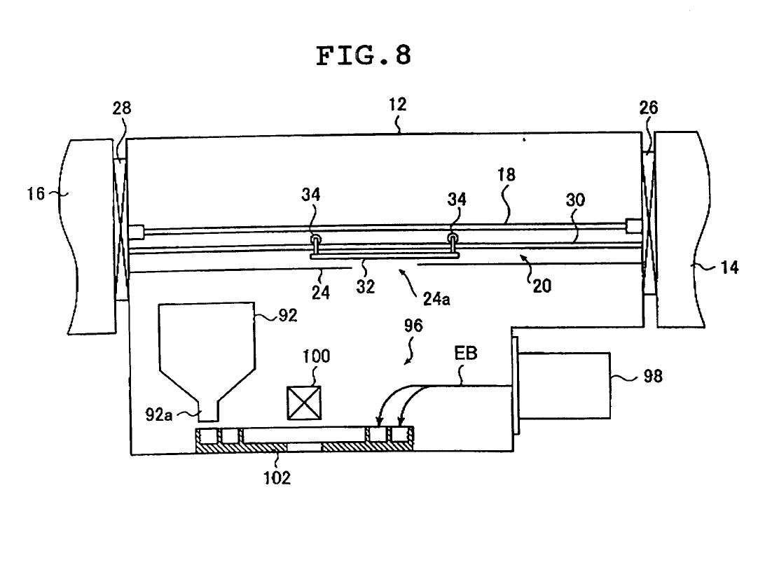

FIG. 8 schematically shows a vacuum deposition apparatus 118 as still a further embodiment of the vacuum deposition apparatus of the present invention, which is arranged in such a manner that, in the load-lock type of vacuum deposition apparatus 10 shown in FIG. 1, a heating evaporator such as the heating evaporator 96 shown in FIG. 6, having a 90° deflecting straight-beam gun constituted by a straight-beam gun 98 and a deflecting coil 100, a rotary crucible 102 having a channel 102c for containing cesium bromide and a channel 102e for containing europium bromide, and a material tank 92 is used instead of the heating evaporator 22.

The components of the vacuum deposition apparatus 118 shown in FIG. 8 are the same as the corresponding components described above.

The present invention is not limited to the above-described load-lock type of vacuum deposition apparatus and can be applied to vacuum deposition apparatuses of various constructions.

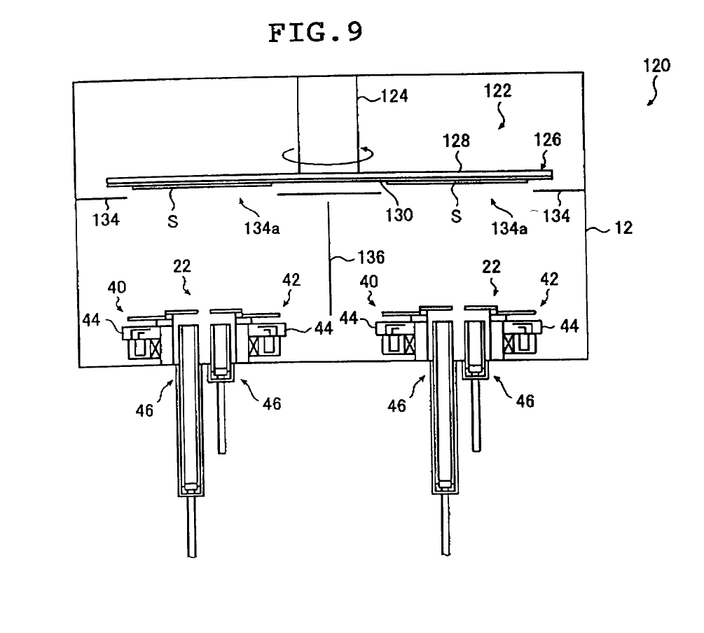

FIG. 9 schematically shows still a further embodiment of the vacuum deposition apparatus of the present invention. The apparatus shown in FIG. 9 has various components common used in common in the vacuum deposition apparatus 10 shown in FIG. 1. The same components as those in the apparatus shown in FIG. 1 are indicated by the same reference symbols. A description will be given mainly of different portions.

The vacuum deposition apparatus 120 shown in FIG. 9 uses a substrate rotating mechanism 122 which rotates while holding substrates S.

The substrate rotating mechanism 122 is constituted by a rotary drive source 124 and a turn table 126. The turn table 126 is a disk formed of an upper-side main portion 128 and a lower-side (heating evaporator 22 side) sheath heater 130. A plurality of substrates S are supported by being secured to the lower surface of the turn table 126 at predetermined positions. The turn table 126 is rotated at a predetermined speed about its rotating shaft corresponding to its center by the rotary drive source 124. The substrate S may be secured to the turn table 126 by a well-known means using a holder or the like functioning also as a mask, the film deposition surface of each substrate S facing downward.

Also in this illustrated embodiment, a vacuum pump is connected to the vacuum chamber 12 and the interior of the vacuum chamber 12 is separated into upper and lower sections by a partition 134, as are those in the above-described embodiment. The substrate rotating mechanism 122 is placed in the upper section while two heating evaporators 22 are placed in the lower section. Each heating evaporator 22 is the same as that shown in FIG. 2. The same components are indicated by the same reference symbols and the detailed description for them will not be repeated. Each heating evaporator 22 is placed at a position corresponding to the locus along which the substrates are rotated by the turn table 126, and an opening 134a is formed in the partition 134 at the position corresponding to each heating evaporator 22. The number of heating evaporators 22 is not limited to two. One heating evaporator 22 or three or more heating evaporators 22 may be provided.

Further, a second partition 136 is placed in the vacuum chamber 12 so as to separate the lower section generally into spaces corresponding to the heating evaporators 22.

In the thus-constructed vacuum deposition apparatus 120, the substrates S are attached to the turn table 126 at the predetermined positions, and the vacuum chamber 12 is thereafter closed and decompressed.

When the predetermined degree of vacuum in the interior of the vacuum chamber 12 is reached, the turn table 126 is rotated at the predetermined speed by the rotary drive source 124. While the turn table 126 is being rotated, film-forming materials (cesium bromide and europium bromide) are heated and evaporated in the heating evaporators 22 in the same manner as in the above-described embodiment of the vacuum deposition apparatus, thereby forming a phosphor layer of CsBr:Eu on the substrates S. When the film-forming material at one of the evaporation positions is used up, the corresponding material feeding means 46 feeds the material in the same manner as that in the above-described embodiment of the vacuum deposition apparatus.

After the completion of film deposition, the rotation of the turn table 126 is stopped, the vacuum chamber 12 is opened and the substrates S on which the film deposition of the phosphor layer has been completed are taken out. If film deposition is again performed, film deposition may be performed in the same manner by loading substrates S.

Also in the vacuum deposition apparatus using the above-described substrate rotating mechanism 122, any of the heating evaporators (material feeding means) shown in FIGS. 3A to 7B can be used. Also, different material feeding means may be used with respect to the film-forming materials.

The vacuum deposition apparatus of the present invention is not limited to the above-described load-lock-type vacuum deposition apparatuses and the apparatus using the substrate rotating mechanism. For example, the invention can also be applied to any of other various vacuum deposition apparatuses, e.g., a batch-type vacuum deposition apparatus in which film deposition is performed on only one substrate.

The vacuum deposition apparatuses of the present invention have been described in detail. Needless to say, the present invention is not limited to the above-described embodiments, and various changes and modifications of the apparatuses described above may be made without departing from the gist and scope of the invention.

For example, while in the above-described embodiments of the vacuum deposition apparatus, one or two two-source heating evaporators are provided, the present invention is not limited to this. Three or more two-source (multiple-source) heating evaporators may be used according to the necessary evaporation rates for film formation. Also, a combination of heating evaporators for different numbers of film-forming materials, e.g., a combination of a one-source heating evaporator and a two-source (multiple-source) heating evaporator may be used according to the composition of the film to be formed, etc. Further, in a case where the vacuum deposition apparatus is arranged to have a plurality of heating evaporators, a combination of heating evaporators of different constructions may be used.

In the vacuum deposition apparatus of the present invention, a melting step in which granular film-forming materials contained in hearths or crucible sections or the like are molten before film deposition may be performed if required.

According to the present invention, as described above, a thick film having a thickness exceeding 200 μm can be formed or deposited by the two-source vacuum deposition. For example, film deposition for a phosphor layer on a (stimulable) phosphor sheet or the like can be suitably performed.

What is claimed is:

1. A vacuum deposition apparatus comprising:
a vacuum chamber;
a plurality of evaporation positions set in said vacuum chamber and provided with film-forming materials in such a way that a film-forming material is placed at an evaporation position;
heating means for heating each of said film-forming materials, and arranged in correspondence with each of said plurality of evaporation positions; and
feeding means for feeding one of said film-forming materials into one of said plurality of evaporation positions during film deposition, and arranged in correspondence with at least one of said plurality of evaporation positions.

2. The vacuum deposition apparatus according to claim 1,
wherein said heating means comprises: at least one of an electron gun which emits an electron beam onto said film-forming material placed at said evaporation position to heat and evaporate said film-forming material; or
resistance heating means which applies resistance heating to said film-forming material placed at said evaporation position to evaporate said film-forming material.

3. The vacuum deposition apparatus according to claim 2,
wherein said electron gun is a deflecting type electron gun.

4. The vacuum deposition apparatus according to claim 1,
wherein said feeding means feeds said film-forming material into said evaporation position according to consumption of said film-forming material being evaporated at said evaporation position.

5. The vacuum deposition apparatus according to claim 1,
wherein a container for containing one film-forming material is placed at said evaporation position corresponding to at least one of said two or more film-forming materials which are different from each other.

6. The vacuum deposition apparatus according to claim 1,
wherein said feeding means comprises:
a cylinder projecting down from said evaporation position through and out of said vacuum chamber and being filled with said film-forming material;
a piston loosely fitted in said cylinder and moving along a vertical direction; and
a motor for driving said piston.

7. The vacuum deposition apparatus according to claim 1,
wherein said feeding means comprises;
a rail having a groove extending in a direction to be filled with said film-forming material and extending sideward from said evaporation position through and out of said vacuum chamber;
a piston fitted to slide and reciprocate in said groove; and
a motor for driving said piston.

8. The vacuum deposition apparatus according to claim 1,
wherein said feeding means comprises;
a film deposition turret on which a plurality of containers containing said one of said film-forming materials are laid on its identical circumference and which is rotated such that said containers laid on said film deposition turret are supplied into said evaporation position one after another; and
rotary drive means for driving said film deposition turret to be rotated.

9. The vacuum deposition apparatus according to claim 8,
wherein said feeding means further comprises:
discharge means for discharging an emptied container from said film deposition turret when said one of said film-forming materials contained therein is used up.

10. The vacuum deposition apparatus according to claim 8,
wherein said feeding means further comprises:
a feed turret arranged close to said film deposition turret to lay a plurality of containers containing said one of said film-forming materials along its identical circumference thereon;
rotary drive means for driving said film deposition turret to be rotated;
pressing means for pressing said containers laid on said feed turret in a radial direction when being close to said film deposition turret and moving said containers from said feed turret to said film deposition turret; and
discharge means for discharging an emptied container from said film deposition turret when said one of said film-forming material contained therein is used up.

11. The vacuum deposition apparatus according to claim 1,
wherein said feeding means comprises:
a rotary crucible having a circular groove for containing said film-forming material and passing through said evaporation position; and
rotary drive means for driving said rotary crucible to be rotated.

12. The vacuum deposition apparatus according to claim 11,
wherein said feeding means further comprises:
a film-forming material tank for feeding said film-forming material into an empty portion of said groove, which is apart from said evaporation position.

13. The vacuum deposition apparatus according to claim 11,
wherein said feeding means comprises:
a plurality of rotary crucibles to be rotated about a same center; and
rotary drive means for driving each of said plurality of rotary crucibles to be rotated.

14. The vacuum deposition apparatus according to claim 13,
wherein said heating means comprises:
a 90° deflecting electron gun including a straight-beam type electron gun and a 90° deflecting coil, said 90° deflecting electron gun emitting an electron beam onto said film-forming material placed at said evaporation position, and thereby heating and evaporating said film-forming material.

15. The vacuum deposition apparatus according to claim 1,
wherein said plurality of evaporation positions are provided with a crucible having a plurality of sets of containing portions which contain a plurality of corresponding film-forming materials respectively, and wherein said feeding means comprises:
a sub chamber for containing a new replacement crucible having the same constitution as said crucible and fixed to the outside of said vacuum chamber and;
a gate valve for communicating said sub chamber with said vacuum chamber; and
a crucible interchange mechanism for interchanging said used crucible in said vacuum chamber with a new replacement crucible and provided in said sub chamber.

16. The vacuum deposition apparatus according to claim 1,
wherein said film-forming material includes two or more types of film-forming materials which are different from each other.

17. The vacuum deposition apparatus according to claim 1,
wherein said film-forming material includes cesium halide and europium halide to form a phosphor layer made of a stimulable phosphor sheet.

18. The vacuum deposition apparatus according to claim 1,
wherein said film-forming material includes cesium halide and europium halide to form a phosphor layer made of a stimulable phosphor sheets, and
wherein said heating means includes:
an electron gun for emitting an electron beam onto said cesium halide placed at said evaporation position and thereby heating and evaporating said cesium halide; and
resistance heating means for applying resistance heating on said europium halide placed at said evaporation position and thereby heating and evaporating said europium halide.
